(19) United States
(12) Patent Application Publication
(10) Pub. No.: US 2025/0107264 A1
(43) Pub. Date: Mar. 27, 2025

(54) APPARATUS, SYSTEM, AND MOVING BODY

(71) Applicant: CANON KABUSHIKI KAISHA, Tokyo (JP)

(72) Inventors: HIROYUKI TSUCHIYA, Tokyo (JP); KAZUHIRO MORIMOTO, Kanagawa (JP)

(21) Appl. No.: 18/894,748

(22) Filed: Sep. 24, 2024

(30) Foreign Application Priority Data
Sep. 27, 2023 (JP) 2023-166369

(51) Int. Cl. H01L 27/146

(52) U.S. Cl. CPC H10F 39/811

(57) ABSTRACT

An apparatus includes a plurality of avalanche photodiodes, a plurality of transistors connected to the plurality of avalanche photodiodes and configured to control occurrence of avalanche multiplication, a first wiring layer configured to transmit a control signal to be input to gates of the plurality of transistors, and a second wiring layer configured to read signals from the avalanche photodiodes, wherein the plurality of avalanche photodiodes includes a first group of avalanche photodiodes arranged in a first direction, wherein the plurality of transistors includes a first group of transistors connected to the first group of avalanche photodiodes, wherein the first wiring layer is connected in common to the first group of transistors, and wherein the first wiring layer has a thickness greater than a thickness of the second wiring layer.

### BACKGROUND

### Technical Field

The aspect of the embodiments relates to an apparatus, a system, and a moving body.

### Description of the Related Art

Photoelectric conversion apparatuses that can detect weak light of a single-photon level by utilizing avalanche multiplication have been known. Japanese Patent Application Laid-Open No. 2023-61644 discusses a photoelectric conversion apparatus including a control unit that enables occurrence of avalanche multiplication by recharging voltages applied between the anodes and cathodes of avalanche photodiodes.

The photoelectric conversion apparatus discussed in Japanese Patent Application Laid-Open No. 2023-61644 has room for consideration regarding the configuration of wiring for inputting a control signal from the control unit to transistors that control the occurrence of avalanche multiplication.

### SUMMARY

According to an aspect of the embodiments, an apparatus includes a plurality of avalanche photodiodes, a plurality of transistors connected to the plurality of avalanche photodiodes and configured to control occurrence of avalanche multiplication, a first wiring layer configured to transmit a control signal to be input to gates of the plurality of transistors, and a second wiring layer configured to read signals from the avalanche photodiodes, wherein the plurality of avalanche photodiodes includes a first group of avalanche photodiodes arranged in a first direction, wherein the plurality of transistors includes a first group of transistors connected to the first group of avalanche photodiodes, wherein the first wiring layer is connected in common to the first group of transistors, and wherein the first wiring layer has a thickness greater than a thickness of the second wiring layer.

Further features of the disclosure will become apparent from the following description of exemplary embodiments with reference to the attached drawings.

### BRIEF DESCRIPTION OF THE DRAWINGS

FIG. 1 is a schematic diagram illustrating a photoelectric conversion apparatus according to an exemplary embodiment.

FIG. 2 is a schematic diagram illustrating a pixel substrate of the photoelectric conversion apparatus according to the exemplary embodiment.

FIG. 3 is a schematic diagram illustrating a circuit substrate of the photoelectric conversion apparatus according to the exemplary embodiment.

FIG. 4 illustrates a configuration example of a pixel circuit of the photoelectric conversion apparatus according to the exemplary embodiment.

FIGS. 5A and 5B are schematic diagrams illustrating the driving of a pixel circuit of the photoelectric conversion apparatus according to the exemplary embodiment.

FIG. 6 is a schematic diagram illustrating pixel circuits according to a first exemplary embodiment.

FIG. 7 is a schematic block diagram of a photoelectric conversion apparatus according to the first exemplary embodiment.

FIG. 8 is a schematic diagram illustrating a relationship between the pixels and control signals of the photoelectric conversion apparatus according to the first exemplary embodiment.

FIGS. 9A and 9B are schematic sectional views illustrating a wiring structure of the photoelectric conversion apparatus according to the first exemplary embodiment.

FIGS. 10A and 10B are diagrams illustrating an issue.

FIGS. 11A and 11B are schematic plan views of wiring structures of the photoelectric conversion apparatus according to the first exemplary embodiment.

FIG. 12 is a schematic view illustrating a relationship between the pixels and control signals of a photoelectric conversion apparatus according to a second exemplary embodiment.

FIG. 13 is a schematic block diagram of a photoelectric conversion apparatus according to a third exemplary embodiment.

FIG. 14 is a functional block diagram of a photoelectric conversion system according to a fourth exemplary embodiment.

FIGS. 15A and 15B are functional block diagrams of a photoelectric conversion system according to a fifth exemplary embodiment.

FIG. 16 is a functional block diagram of a photoelectric conversion system according to a sixth exemplary embodiment.

FIG. 17 is a functional block diagram of a photoelectric conversion system according to a seventh exemplary embodiment.

FIGS. 18A and 18B are perspective views of a photoelectric conversion system according to an eighth exemplary embodiment.

FIGS. 19A and 19B are a front view and a rear view of a photoelectric conversion system according to a ninth exemplary embodiment.

FIG. 20 is a functional block diagram of a photoelectric conversion system according to a tenth exemplary embodiment.

### DESCRIPTION OF THE EMBODIMENTS

Exemplary embodiments described below are intended to embody the technical concept of the disclosure and not limit the disclosure. The sizes and positional relationship of members illustrated in the drawings may be exaggerated for the sake of clear description. In the following description, similar components are denoted by the same reference numerals, and a description thereof may be omitted.

The exemplary embodiments of the disclosure will be described in detail below with reference to the drawings. In the following description, terms indicating specific directions and positions (for example, “top”, “bottom”, “right”, and “left”, and other terms including these) are used as appropriate. These terms are used to facilitate the understanding of the exemplary embodiments with reference to the drawings, and the technical scope of the disclosure is not limited by the meanings of the terms.

As employed herein, a plan view refers to a view in a direction perpendicular to the light incident surface of a semiconductor layer. A cross-sectional view refers to a view of a cross section perpendicular to the light incident surface of the semiconductor layer. In a case where the light incident surface of the semiconductor layer is a microscopically rough surface, the plan view is defined with reference to the light incident surface of the semiconductor layer seen macroscopically.

The semiconductor layer has a first surface and a second surface that is opposite to the first surface and on which light is incident.

As employed herein, a depth direction refers to a direction from the first surface, where avalanche photodiodes (APDs) are disposed, to the second surface of the semiconductor layer. The “first surface” may hereinafter be referred to as a “front”, and the “second surface” as a “back”.

In the following description, the anodes of the APDs are fixed at a constant potential, and signals are taken out from the cathodes. A semiconductor region of first conductivity type where charges of the same polarity as that of signal charges are majority carriers is therefore an N-type semiconductor region. A semiconductor region of second conductivity type where charges of opposite polarity to that of signal charges are majority carriers is a P-type semiconductor region. The exemplary embodiments also hold even in a case where the cathodes of the APDs have a fixed potential and signals are taken out from the anodes. In such a case, a semiconductor region of the first conductivity type where charges of the same polarity as that of signal charges are majority carriers is a P-type semiconductor region. A semiconductor region of the second conductivity type where charges of opposite polarity to that of signal charges are majority carriers is an N-type semiconductor region. While the following description deals with a case where one node of the APD has a fixed potential, both nodes may be variable in potential.

In the following exemplary embodiments, connections between circuit elements may be described. In such a case, the elements in question are regarded as being connected even in a case where another element is interposed between the elements in question, unless otherwise specified. For example, in a case where an element A is connected to one node of a capacitive element C having a plurality of nodes, and an element B is connected to another node, the elements A and B are regarded as being connected, unless otherwise specified.

Metal members described in this specification, such as wiring and pads, may be composed of a single-element metal or a mixture (alloy). For example, wiring described as copper wiring may be composed of copper alone, or mainly contain copper and further contain other components. For example, pads to be connected to external terminals may be composed of aluminum alone, or mainly contain aluminum and further contain other components. The copper wiring and aluminum pads mentioned here are just examples, and various metals may be used instead.

The wiring and pads mentioned here are merely examples of the metal members used in a photoelectric conversion apparatus, and other metal members are also applicable.

In the following exemplary embodiments, an imaging apparatus will mainly be described as an example of the photoelectric conversion apparatus. However, the exemplary embodiments are not limited to imaging apparatuses and can be applied to other examples of the photoelectric conversion apparatus. The other examples include a distance measuring apparatus (apparatus for distance measurement using focus detection or time of flight [ToF]) and a light metering apparatus (apparatus for measuring the amount of incident light).

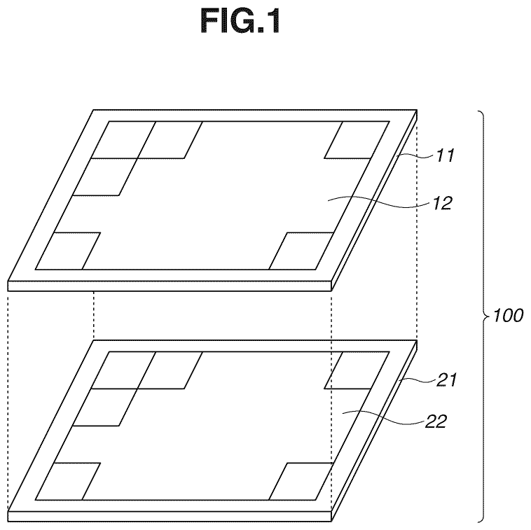

A configuration common for the photoelectric conversion apparatuses and their driving methods according to the exemplary embodiments of the disclosure will be described with reference to FIG. 1 to FIGS. 5A and 5B.

FIG. 1 is a diagram illustrating a configuration of a photoelectric conversion apparatus 100 according to an exemplary embodiment of the disclosure. The following description will be given by using a case where the photoelectric conversion apparatus 100 is a stacked photoelectric conversion apparatus as an example. More specifically, a photoelectric conversion apparatus where two substrates, or a pixel substrate 11 and a circuit substrate 21, are stacked and electrically connected will be described as an example. However, the photoelectric conversion apparatus is not limited thereto. For example, as will be described below, a photoelectric conversion apparatus may include a common semiconductor layer on which both the components included in the pixel substrate 11 and the components included in the circuit substrate 21 are disposed. In the following description, the photoelectric conversion apparatus including the common semiconductor layer on which the components included in the pixel substrate 11 and the components included in the circuit substrate 21 are disposed may be referred to as a non-stacked photoelectric conversion apparatus.

The pixel substrate 11 includes a first semiconductor layer including photoelectric conversion units 102 to be described below, and a first wiring structure. The circuit substrate 21 includes a second semiconductor layer including circuits such as signal processing circuits 103 to be described below, and a second wiring structure. The photoelectric conversion apparatus 100 is constituted by stacking the second semiconductor layer, the second wiring structure, the first wiring structure, and the first semiconductor layer in order.

FIG. 1 illustrates a back-illuminated photoelectric conversion apparatus where light is incident on the second surface and the circuit substrate 21 is located at the first surface opposite to the second surface. In the case of a non-stacked photoelectric conversion apparatus, the surface where the transistors of the signal processing circuits are disposed will be referred to as the first surface. In the case of the back-illuminated photoelectric conversion apparatus, the second surface opposite to the first surface of the semiconductor layer serves as the light incident surface. In the case of a front-illuminated photoelectric conversion apparatus, the first surface of the semiconductor layer serves as the light incident surface.

While the pixel substrate 11 and the circuit substrate 21 are hereinafter described to be diced chips, the substrates 11 and 21 are not limited to chips. For example, each substrate may be a wafer. The substrates may be stacked in the wafer state and then diced, or diced into chips and then stacked and bonded. Alternatively, a semiconductor layer thinned from a substrate state and on which a wiring structure is stacked is also referred to as a substrate.

The pixel substrate 11 includes a pixel region 12. The circuit substrate 21 includes a circuit region 22 for processing signals detected in the pixel region 12.

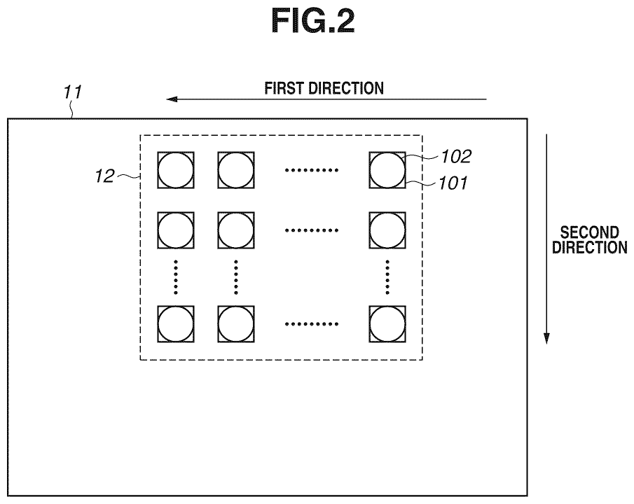

FIG. 2 is a layout diagram of the pixel substrate 11. A plurality of pixels 101 each including a photoelectric conversion unit 102 that includes an APD is two-dimensionally arranged to form the pixel region 12. In other words, some of the plurality of APDs (first group of APDs) are arranged in a first direction. Some of the plurality of APDs (second group of APDs) are arranged in a second direction orthogonal to the first direction.

The pixels 101 are typically pixels for forming an image. However, when used for ToF purposes, the pixels 101 do not necessarily need to form an image. In other words, the pixels 101 may be pixels for measuring the time of arrival and the amount of light.

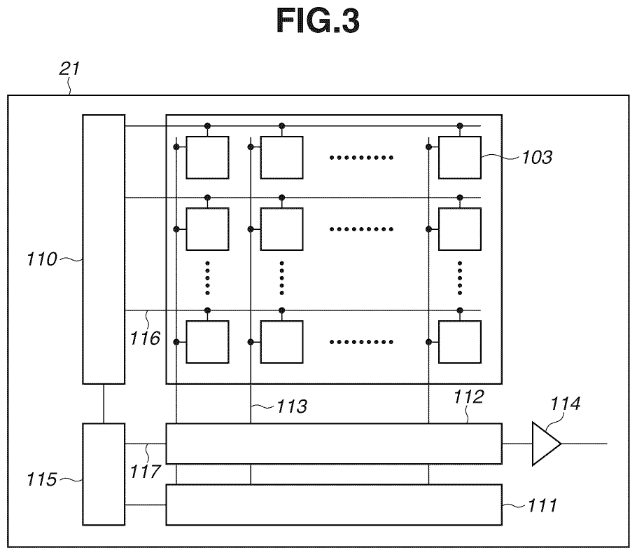

FIG. 3 is a block diagram of the circuit substrate 21. The circuit substrate 21 includes signal processing units 103 for processing charges photoelectrically converted by the photoelectric conversion units 102 of FIG. 2, a reading circuit 112, a control pulse generation unit 115, a horizontal scanning circuit unit 111, signal lines 113, and a vertical scanning circuit unit 110.

The photoelectric conversion units 102 of FIG. 2 and the signal processing units 103 of FIG. 3 are electrically connected by connection wiring provided pixel by pixel.

The vertical scanning circuit unit 110 receives control pulses supplied from the control pulse generation unit 115 and supplies the control pulses to the pixels 101. A logic circuit such as a shift register and an address decoder is used for the vertical scanning circuit unit 110.

The control pulse generation unit 115 includes a signal generation unit that generates a control signal VR for switches to be described below. As will be described below, the signal generation unit generates a pulse signal for controlling the switches. The signal generation unit may generate a common control signal VR for all the plurality of pixels 101 in the pixel region 12, or generate a common control signal VR for some of the plurality of pixels 101 in the pixel region 12. In generating the common pulse signal (control signal) VR, at least one of the period, the number of pulses, and the pulse width of a pulse signal P_EXP for controlling an exposure period is set common based on the exposure period. In the case of generating the control signal VR for some of the plurality of pixels 101, the control signal VR can be generated using an input signal VR output from the control pulse generation unit 115 and the pulse signal P_EXP for controlling the exposure period. The control pulse generation unit 115 includes a frequency divider circuit, for example. This enables simple control and can reduce an increase in the number of elements. The control pulse generation unit 115 supplies the pulse signal VR.

The signals output from the photoelectric conversion units 102 of the respective pixels 101 are processed by the signal processing units 103. The signal processing units 103 include counters and memories, and digital values are stored in the memories.

To read the signals from the memories of the respective signal processing units 103 where the digital signals are stored, the horizontal scanning circuit unit 111 inputs control pulses for sequentially selecting columns to the signal processing units 103.

The signal processing units 103 corresponding to pixels 101 selected by the vertical scanning circuit unit 110 output signals to the signal lines 113 when the columns are selected. The signal lines 113 are connected to the signal processing units 103 arranged in the column direction, and serve as respective output lines common for the signal processing units 103.

The signals output to the signal lines 113 are output to a recording unit or a signal processing unit outside the photoelectric conversion apparatus 100 via an output circuit 114.

In FIG. 2, the plurality of pixels 101 may be one-dimensionally arranged in the pixel region 12. The functions of the signal processing units 103 do not necessarily need to be provided for all the pixels 101 on a one-on-one basis. For example, one signal processing unit 103 may be shared by a plurality of pixels 101, and the signal processing may be sequentially performed.

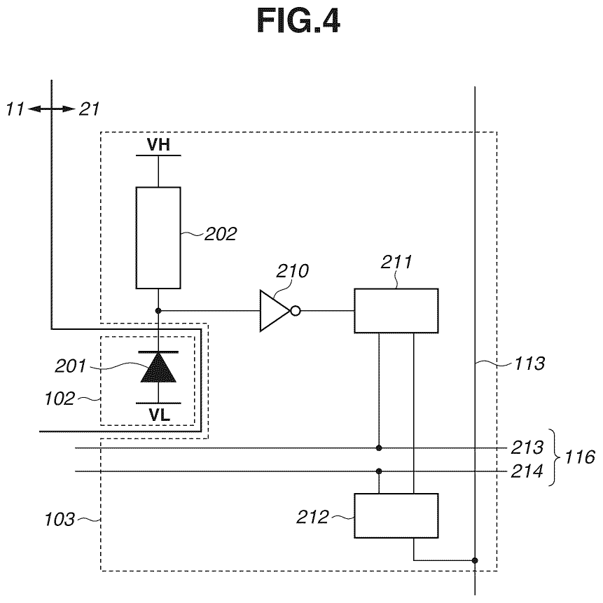

FIG. 4 is an example of a block diagram including an equivalent circuit of FIGS. 2 and 3. In FIG. 2, the photoelectric conversion units 102 including the APDs 201 are disposed on the pixel substrate 11. The other members are disposed on the circuit substrate 21.

Each APD 201 generates a charge pair corresponding to incident light through photoelectric conversion. A voltage VL (first voltage) is supplied to the anode of the APD 201. A voltage VH (second voltage) higher than the voltage VL supplied to the anode is supplied to the cathode of the APD 201. A reverse bias voltage for the APD 201 to perform an avalanche multiplication operation is supplied across the anode and the cathode. With such a voltage supplied, a change occurring from the incident light causes avalanche multiplication to generate an avalanche current.

The reverse bias voltage can be supplied in a Geiger mode and a linear mode. In the Geiger mode, the ADP operates with the potential difference between the anode and the cathode higher than a breakdown voltage. In the linear mode, the APD operates with the potential difference between the anode and the cathode near the breakdown voltage or lower than or equal to the breakdown voltage. The APD operating in the Geiger mode is referred to as a single-photon avalanche diode (SPAD). For example, the voltage VL (first voltage) is −30 V, and the voltage VH (second voltage) is 1 V. The APD 201 may operate in the linear mode or the Geiger mode.

A switch 202 is connected to a control line through which the voltage (driving voltage) VH is supplied and the APD 201. The switch 202 is connected to one of the anode and cathode of the APD 201.

The switch 202 switches the potential difference between the anode and cathode of the APD 201 between a first potential that causes avalanche multiplication and a second potential that does not cause avalanche multiplication. In the following description, switching from the second potential difference to the first potential difference will be referred to as turning on the switch 202. Switching from the first potential difference to the second potential difference will be referred to turning off the switch 202. The switch 202 functions as a quenching element. The switch 202 has a function of serving as a load circuit (quenching circuit) during avalanche signal multiplication, whereby the voltage supplied to the APD 201 is reduced to suppress avalanche multiplication (quenching operation). The switch 202 also has a function of passing a current as much as the voltage drop due to the quenching operation, whereby the voltage supplied to the APD 201 is restored to the driving voltage VH (recharge operation). In other words, the switch 202 functions as a control circuit for controlling the occurrence of avalanche multiplication in the APD 201.

The switch 202 may be constituted by a metal-oxide-semiconductor (MOS) transistor, for example. The control signal VR for the switch 202, supplied from the signal generation unit, is applied to the gate electrode of the MOS transistor constituting the switch 202. In the present exemplary embodiment, the turning-on and-off of the switch 202 is controlled by controlling the voltage applied to the gate electrode of the switch 202.

The signal processing unit 103 includes a waveform shaping unit 210, a counter circuit 211, and a selection circuit 212. As employed herein, the signal processing unit 103 can include at least one of the waveform shaping unit 210, the counter circuit 211, and the selection circuit 212.

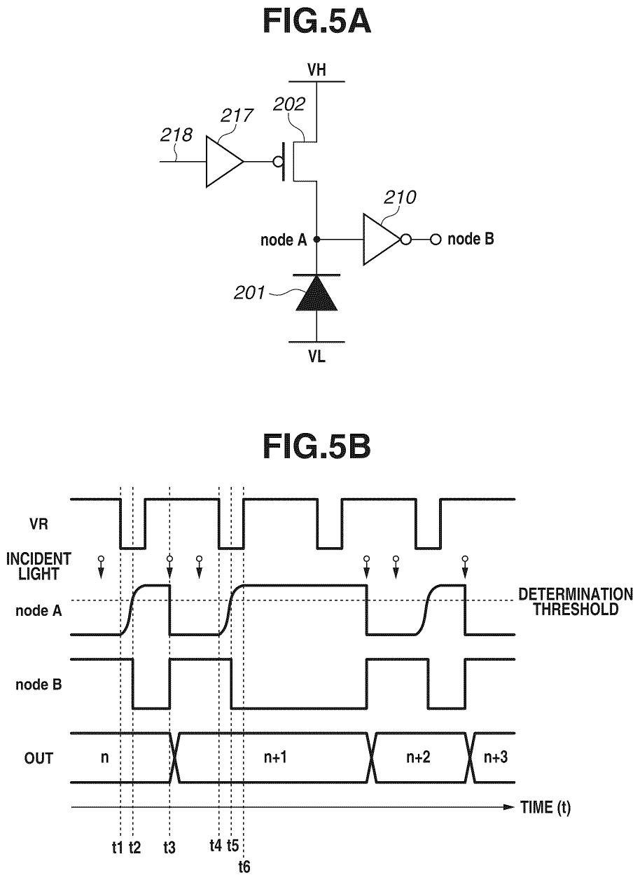

The waveform shaping circuit 210 shapes a potential change at the cathode of the APD 210 acquired during photon detection and outputs a pulse signal. The input node of the waveform shaping unit 210 will be referred to as node A, and the output node as node B. The waveform shaping unit 210 changes the output potential from node B depending on whether the input potential to node A is higher than or equal to a predetermined value or lower than the predetermined value. For example, in FIG. 5B, in a case where the input potential to node A is a high potential at or above a determination threshold, the output potential from node B changes to a low level. In a case where the input potential to node A is a low potential below the determination threshold, the output potential from node B changes to a high level. For example, an inverter circuit is used as the waveform shaping circuit 210. While FIG. 4 illustrates an example where one inverter is used as the waveform shaping unit 210, a circuit including a plurality of inverters connected in series may be used. Other circuits having a waveform shaping effect may be used.

While the quenching operation and the recharge operation using the switch 202 can be performed in response to the avalanche multiplication in the APD 201, a charge occurring in the APD 201 may fail to be determined as an output signal depending on the photon detection timing. For example, that the APD 201 causes avalanche multiplication and node A changes to the low level, and the recharge operation is being performed. In general, the determination threshold of the waveform shaping unit 210 is set at a potential higher than the potential difference at which the APD 201 causes avalanche multiplication. In a case where a photon is incident on the APD 201 when the potential of node A is lower than the determination threshold due to the recharge operation and is capable of causing avalanche multiplication in the APD 201, avalanche multiplication occurs in the APD 201 and the voltage of node A drops. Since the potential of node A drops from a voltage lower than the determination threshold, there occurs no potential change across the determination threshold and the output potential from node B remains unchanged. The photon detection is therefore not determined to be a signal despite the occurrence of the avalanche multiplication. In particular, under high illuminance, photons are successively incident on the APD 201 in a short period and the incident light is thus less likely to be determined as a signal. As a result, there tends to be a discrepancy between the actual number of incident photons and the output signal despite high illuminance.

By contrast, in a case where the control signal VR is applied to the switch 202 to turn the switch 202 on and off, photons successively incident on the APD 201 in a short time can be determined as signals. Referring to FIGS. 5A and 5B, an example where the control signal VR is a periodic pulse signal will be described. In other words, a mode where the switch 202 is turned on and off at a predetermined clock frequency will be described with reference to FIGS. 5A and 5B. Note that the effect of reducing an increase in the power consumption of the photoelectric conversion apparatus 100 can also be obtained even in a case where the pulse signal is not a periodic signal.

The counter circuit 211 counts the pulse signal output from the waveform shaping circuit 210 and stores the count. The signal (count) stored in the counter circuit 211 is reset when a control pulse pRES is supplied via a driving line 213.

A control pulse pSEL is supplied from the vertical scanning circuit unit 110 of FIG. 1 to the selection circuit 212 via a driving line 214 of FIG. 4 (not illustrated in FIG. 3). The selection circuit 212 switches electrical connection and disconnection between the counter circuit 211 and the signal 113. The selection circuit 212 includes a buffer circuit for outputting a signal, for example.

Switches such as transistors may be disposed between the switch 220 and the APD 201 and between the photoelectric conversion unit 102 and the signal processing unit 103 to switch electrical connection. Similarly, the supply of the voltages VH and VL to the photoelectric conversion unit 102 may be electrically switched using switches such as transistors.

For example, a selection circuit may be interposed between the waveform shaping circuit 210 and the counter circuit 211.

The selection circuit outputs the output signal of the waveform shaping circuit 210 to the counter circuit 211 in a period where a gate signal input from outside the pixel 101 is at a high level. On the other hand, in a period where the gate signal is at a low level, the selection circuit does not output the output signal of the waveform shaping circuit 210 to the counter circuit 211. For example, by inputting a pulse of a nanosecond or picosecond level as the gate signal, a photon that is incident in the period of interest can be selectively detected.

The present exemplary embodiment deals with the configuration using the counter circuit 211. However, the photoelectric conversion apparatus 100 may be configured to obtain pulse detection timing using a time to digital converter (TDC) and a memory instead of the counter circuit 211. Here, the timing of occurrence of the pulse signal output from the waveform shaping circuit 210 is converted into a digital signal by the TDC. To measure the timing of the pulse signal, a control pulse pREF (reference signal) is supplied from the vertical scanning circuit 110 of FIG. 1 to the TDC via a driving line. The TDC obtains a value indicating the input timing of the signal output from each pixel in terms of relative time with reference to the control pulse pREF as the digital signal.

FIGS. 5A and 5B are diagrams schematically illustrating a relationship between the control signal VR for the switch 202, the potential of node A, the potential of node B, and the output signal. In the present exemplary embodiment, in a case where the control signal VR is at a high level, the driving voltage VH is less likely to be supplied to the APD 201. In a case where the control signal VR is at a low level, the driving voltage VH is supplied to the APD 201. For example, the high level of the control signal VR is 1 V, and the low level of the control signal VR is 0 V. The high level of the control signal VR turns the switch 202 off. The low level of the control signal VR turns the switch 202 on. The resistance of the switch 202 when the control signal VR is at the high level is higher than that of the switch 202 when the control signal VR is at the low level. With the control signal VR at the high level, the recharge operation is less likely to occur even when the APD 201 causes avalanche multiplication. The potential supplied to the APD 201 thus falls to or below the breakdown voltage of the APD 201. This stops the avalanche multiplication operation of the APD 201.

As illustrated in FIG. 5A, the switch 202 is constituted by a signal transistor that performs the quenching operation and the recharge operation. This can reduce the number of circuits compared to when the quenching operation and the recharge operation are performed by respective different circuits. In particular, in a case where the counter circuits 211 are disposed for the respective pixels 101 and read the SPAD signals of the respective pixels 101, the circuit areas of the switches 202 are reduced for the sake of disposition of the counter circuits 211. The effect of configuring the switch 202 with a single transistor is therefore significant. A signal from a driving line 218 is input to the transistor constituting the switch 202 via a buffer circuit 217.

At time t1, the control signal VR changes from the high level to the low level to turn the switch 202 on, whereby the recharge operation of the APD 201 is started. As a result, the potential at the cathode of the APD 201 transitions to a high level. A potential difference between the potentials applied to the anode and cathode of the APD 201 then changes to a value at which avalanche multiplication occurs. The potential of the cathode is the same as that of node A. When the potential of the cathode transitions from the low level to the high level, the potential of node A thus reaches or exceeds the determination threshold at time t2. Here, the pulse signal output from node B is reversed from the high level to the low level. The potential difference of the driving voltage VH—the driving voltage VL is then applied to the APD 201. The control signal VR changes from the low level to the high level, and the switch 202 turns off.

Next, at time t3, a photon is incident on the APD 201 to cause avalanche multiplication in the APD 201, and the cathode voltage drops. In other words, the voltage of node A drops. The amount of voltage drop increases further, and the voltage difference applied across the APD 201 decreases. This stops the avalanche multiplication of the APD 210 like time t2, and the voltage level of node A stops dropping beyond a certain value. In the process of dropping, the voltage of node A falls below the determination threshold, and the voltage of node B changes from the low level to the high level. In other words, the portion of the output waveform of node A exceeding the determination threshold is shaped by the waveform shaping unit 210 and output as a signal from node B. The signal is then counted by the counter circuit 211, and the count indicated by the counter signal output from the counter circuit 211 increases by 1 least significant bit (LBS).

While a photon is incident between time t3 and time t4, the voltage level of node A does not exceed the determination threshold since the switch 202 is off and the voltage applied to the APD 201 does not provide a potential difference capable of avalanche multiplication.

At time t4, the control signal VR changes from the high level to the low level, and the switch 202 turns on. As a result, a current that compensates for the voltage drop flows from the driving voltage VH to node A, and the voltage of node A transitions to the original voltage level. At time t5, the voltage of node A reaches or exceeds the determination threshold. The pulse signal of node B is reversed from the high level to the low level.

At time t6, node A settles at the original voltage level, and the control signal VR changes from the low level to the high level. This turns off the switch 202. Subsequently, the potentials of the nodes and signal lines change in response to the control signal VR and the incidence of photons as described for times t1 to t6.

Photoelectric conversion apparatuses according to the exemplary embodiments will now be described. The photoelectric conversion apparatus according to each exemplary embodiment is a stacked photoelectric conversion apparatus as illustrated in FIG. 1.

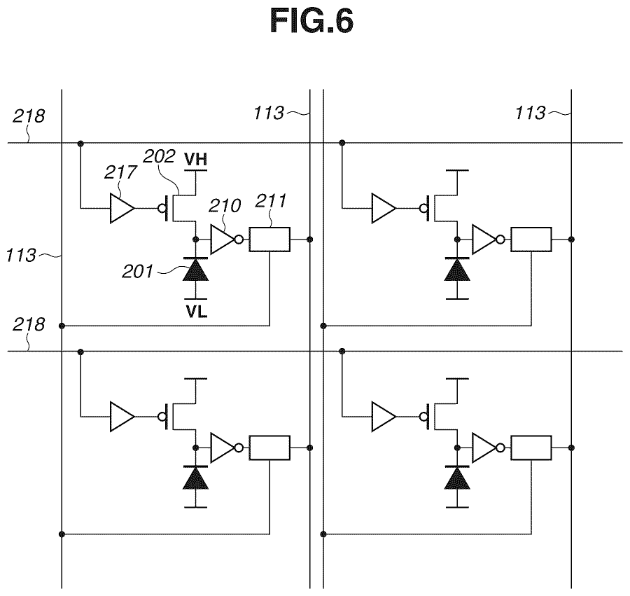

Details of a photoelectric conversion apparatus according to a first exemplary embodiment will be described with reference to FIG. 6 to FIGS. 9A and 9B. FIG. 6 illustrates a circuit configuration of pixel circuits in a case where pixels are arranged vertically in two rows and horizontally in two columns from the right, i.e., in an array of two rows x two columns. While two rows and two columns are extracted and described here, pixels may be arranged in 100 rows or more×100 columns or more, in one embodiment, in an array of 1000 rows or more×1000 columns or more. The greater the number of pixels arranged, the more pronounced the effect of reducing transmission delay according to the present exemplary embodiment.

As illustrated in FIG. 6, the driving lines 218 are connected so that the control signal VR that is a recharge pulse is applied to the gates of the N-type MOS (NMOS) transistors constituting the switches 202 through the driving lines 218. The application of the recharge pulse to the gates of the NMOS transistors controls the turning-on and -off of the switches 202. The gates of the NMOS transistors and the driving lines 218 are connected via buffer circuits 217.

In FIG. 6, the selection circuit 212 illustrated in FIG. 5A is omitted, whereas the selection circuit 212 may be included. The selection circuit 212 may be disposed instead of the counter circuit 211.

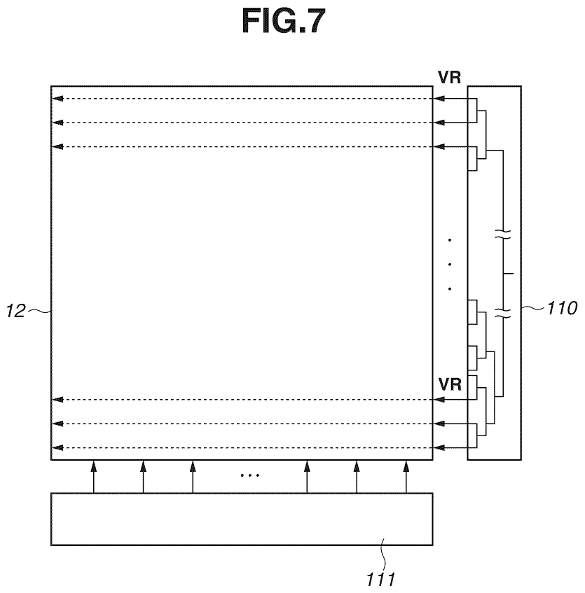

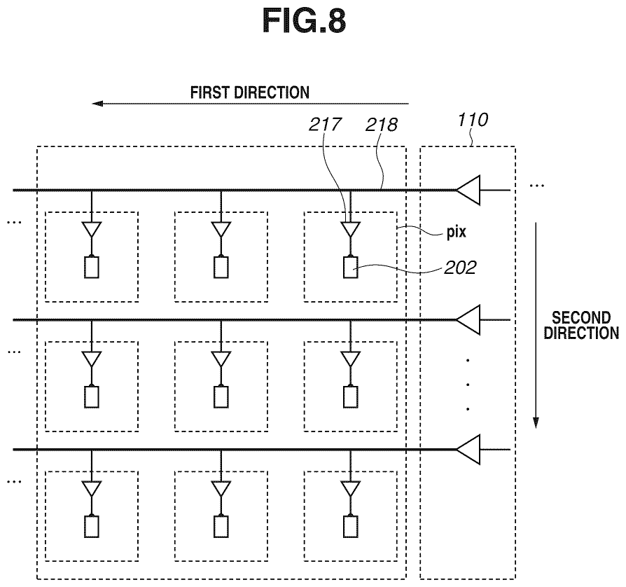

FIG. 7 illustrates a block diagram according to the present exemplary embodiment. FIG. 8 illustrates a block diagram of an extracted part of the pixel region 12 illustrated in FIG. 7. As illustrated in FIG. 7, the vertical scanning circuit unit 110 is located along one side of the pixel region 12. In FIG. 7, the vertical scanning circuit unit 110 is located on the right of the pixel region 12 in a plan view. However, as illustrated in FIG. 3, the vertical scanning circuit unit 110 may be located on the left of the pixel region 12 in a plan view.

As illustrated in FIG. 8, the control signal VR is supplied from the vertical scanning circuit unit 110 to the switches 202 via the driving lines 218. The driving lines 218 are connected so that a common control signal VR is supplied to a plurality of pixels pix (pixels 101) arranged in a row.

In a case where the plurality of pixels is arranged as illustrated in FIG. 8 and the control signal VR is supplied from the common driving lines 218, the transmission timing of the control signal VR can differ between the pixels closest to and the pixels farthest from the vertical scanning circuit unit 110. In particular, the control signal VR is an important signal in controlling whether the APDs 201 are capable of avalanche multiplication. In a case where the transmission timing of the control signal VR differs, the plurality of pixels is unable to be put into a state capable of avalanche multiplication at the same timing, and the plurality of pixels is unable to be exposed at the same timing. The driving lines 218 for transmitting the control signal VR are therefore configured so that the signal transmission delay is less likely to occur. In the present exemplary embodiment, the thickness of the driving lines 218 where the signal transmission delay is to be reduced is increased to lower the wiring resistance and reduce the signal transmission delay. In the vertical scanning circuit unit 110, the control signal VR is transmitted to the driving lines 218 using binary division.

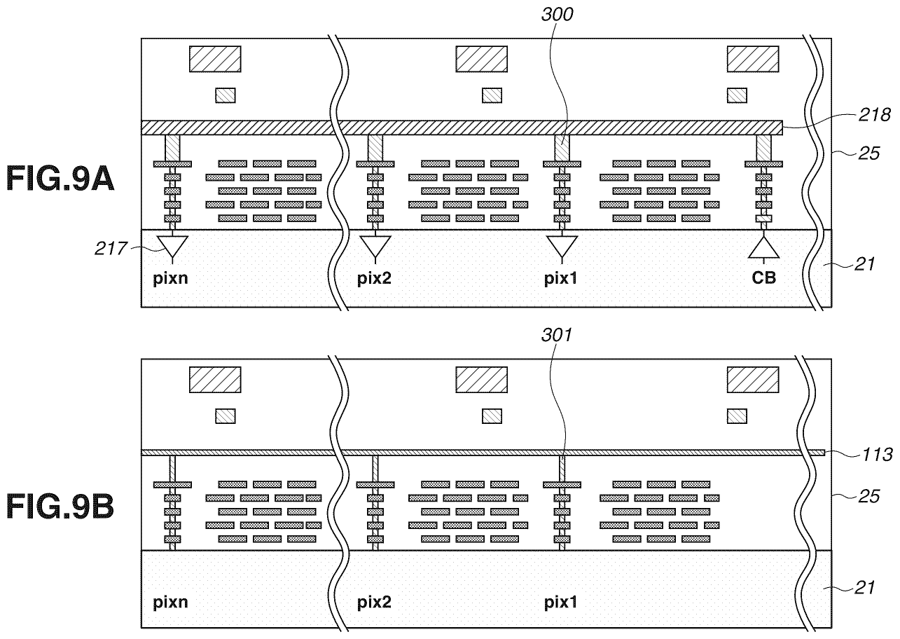

FIGS. 9A and 9B are schematic sectional views of the circuit substrate 21 and a second wiring structure 25. The semiconductor layer constituting the circuit substrate 21 includes the transistors constituting the switches 202 corresponding to the respective pixels pix, as well as the counter circuits 211, the selection circuits 212, and clock buffers CB. The clock buffers CB are semiconductor devices for dividing the control signal VR between a plurality of logic circuits. The second wiring structure 25 is a structure including a plurality of wiring layers in an insulating film. FIG. 9A illustrates the path of the control signal VR input from a clock buffer CB to switches 202 via a first wiring layer constituting a driving line 218. FIG. 9B illustrates a second wiring layer constituting a signal line 113 through which the signals output from the pixels pix pass. As illustrated in FIGS. 9A and 9B, in the present exemplary embodiment, the thickness of the first wiring layer constituting the driving line 218 (also referred to as “the thickness of the driving layer 218”) is greater than the thickness of the second wiling layer constituting the signal line 113 (also referred to as “the thickness of the signal line 113”). This can make the transmission delay of the control signal VR less likely to occur. For example, the driving lines 218 have a thickness 1.2 times or more of the thickness of the signal lines 113. For example, the driving lines 218 may have a thickness in the range of 12 nm to 2000 nm, and the signal lines 113 a thickness in the range of 10 nm to 1000 nm, so that the thickness of the driving lines 218 is greater than that of the signal lines 113. The thickness of the driving lines 218 and that of the signal lines 113 may be compared in terms of the thickness of the driving lines 218 disposed on one wiring layer and that of the signal lines 113 disposed on one wiring layer. The thickness of the driving lines 218 and that of the signal lines 113 are compared in terms of the total thickness of the wiring through which the control signal VR passes and the total thickness of the wiring through which the signals output from the pixels pix pass. For example, in a case where the second wiring structure 25 includes five wiring layers and the control signal VR passes through three of the five wiring layers, the total thickness of the wiring on the three layers can be regarded as the thickness of the driving lines 218. In a case where the signals output from the pixels pix pass through two of the five wiring layers, the total thickness of the wiring on the two layers can be regarded as the thickness of the signal lines 113.

The wiring constituting the driving lines 218 may be aluminum wiring or copper wiring, for example. Of these, copper wiring can provide a lower electrical resistivity. The driving lines 218 may be made of the same material as that of the wiring on other wiring layers, or a different material.

In FIGS. 9A and 9B, contact plugs 300 connecting the wiring constituting the driving line 218 and the wiring directly below have a width greater than that of contact plugs 301 connecting the wiring constituting the signal line 113 and the wiring directly below. This can reduce the contact resistance between the driving line 218 and the contact plugs 300, and can make the transmission delay even less likely to occur. The contact plugs 300 may have the same width as that of the contact plugs 301 or that of contact plugs disposed in lower layers.

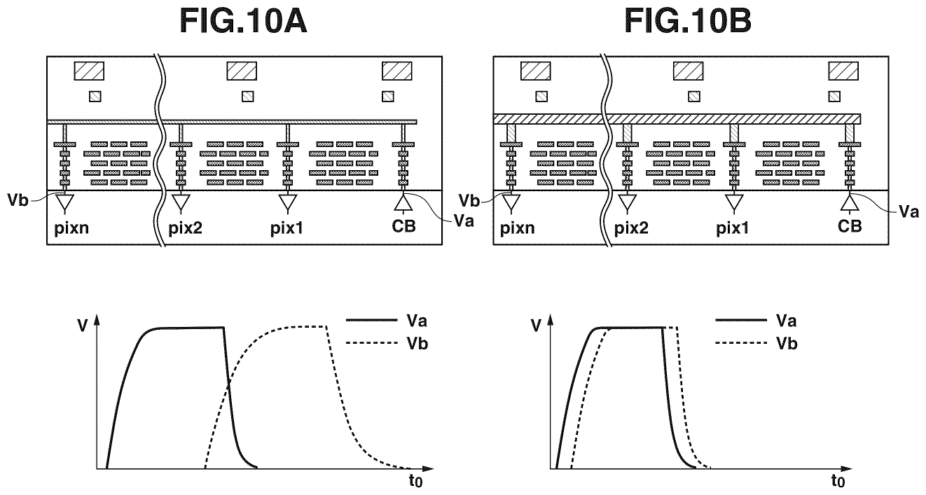

An issue and effects of the present exemplary embodiment will be described with reference to FIGS. 10A and 10B. FIG. 10A is a diagram illustrating an example (comparative example) where the driving line 218 has the same thickness as that of the signal line 113. FIG. 10B is a diagram illustrating the driving line 218 according to the present exemplary embodiment. The vertical axes of the graphs indicate voltage, and the horizontal axes indicate time. In FIGS. 10A and 10B, Va represents the voltage of the clock buffer CB and a change in the voltage over time. Vb represents the voltage of a pixel pixn farthest from the clock buffer CB among the plurality of pixels in the pixel region and a change in the voltage over time.

As illustrated in FIG. 10A, in the comparative example where the thickness of the driving line 218 is not increased, a delay (clock skew) occurs from when a potential is supplied from the clock buffer CB to when the potential is supplied to the pixel pixn. By contrast, as illustrated in FIG. 10B, the increased thickness of the driving line 218 can reduce the delay time until the supplied control signal VR reaches the pixel pixn compared to the comparative example. Since increasing the thickness of all the wiring tends to increase the size of the photoelectric conversion apparatus 100, the thickness of transmission lines where the effect of transmission delay is relatively small, like the signal lines 113, is kept smaller than that of the driving lines 218.

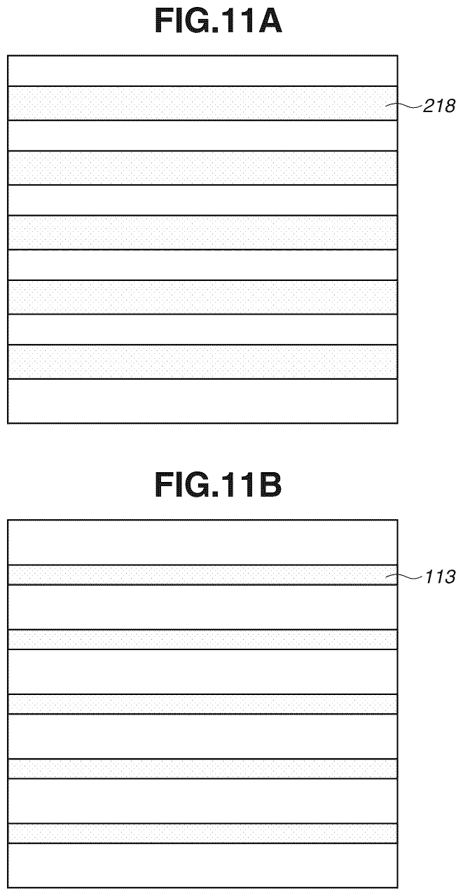

In FIGS. 9A and 9B, the driving lines 218 and the signal lines 113 have different thicknesses. However, such a configuration is not restrictive. For example, as illustrated in the schematic plan views of the first and second wiring layers in FIGS. 11A and 11B, the width of the driving lines 218 may be greater than that of the signal lines 113. For example, the width of the driving lines 218 can be 1.2 times or more greater than that of the signal lines 113. This can also reduce the transmission delay of the control signal VR since the wiring capacitance of the driving lines 218 can be reduced. For example, the driving lines 218 may have a width in the range of 6 nm to 2000 nm, and the signal lines 113 may have a width in the range of 5 nm to 1000 nm.

Both the thickness and width of the driving lines 218 may be increased compared to the thickness and width of the signal lines 113, respectively. The wiring resistance of the driving lines 218 can thereby be lower than that of the signal lines 113.

The thickness of the wiring through which the gate signal to be input to the selection circuit disposed between the waveform shaping unit 210 and the counter circuit 211 passes is greater than that of the signal line 113. A deviation in the transmission timing of the gate signal can lead to detection of a photon that is incident other than during the intended period. Making the thickness of the wiring through which the gate signal passes greater than that of the signal line 113 can reduce a deviation in the transmission timing due to the transmission delay.

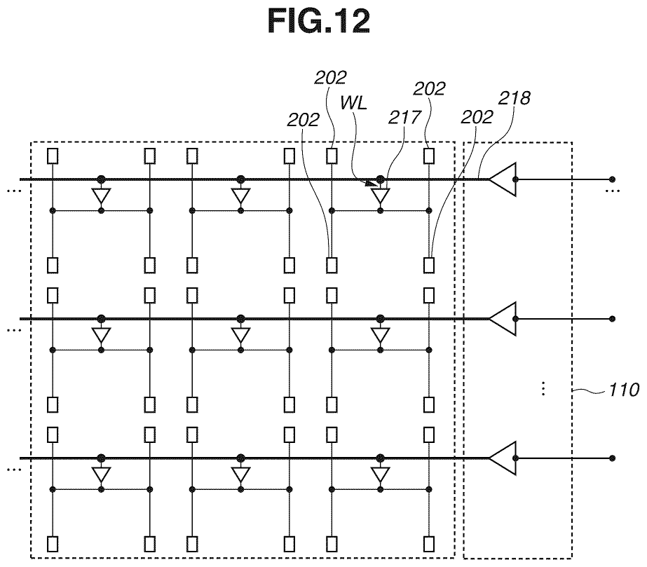

A photoelectric conversion apparatus according to a second exemplary embodiment will be described with reference to FIG. 12. The photoelectric conversion apparatus according to the present exemplary embodiment differs from the first exemplary embodiment in that there is disposed a plurality of buffer circuits 217, and the control signal VR is connected to be input from one buffer circuit 217 to a plurality of quenching elements (switches 202). Except for this point and the points described below, the second exemplary embodiment is similar to the first exemplary embodiment. Some descriptions may therefore be omitted.

In the present exemplary embodiment, a buffer circuit 217 is shared by four pixels. In other words, a buffer circuit 217 is connected so that the control signal VR is input from the buffer circuit 217 to the transistors constituting four switches 202. According to the present exemplary embodiment, the wiring distances from the buffer circuit 217 to the transistors constituting the four switches 202 connected can be the same. This can make transmission delay less likely to occur. Since the number of lines WL between the driving lines 218 and the buffer circuits 217 can be reduced, the transmission delay can be reduced more easily due to reduced wiring capacitance.

Since the number of buffer circuits 217 can be reduced, the area of the circuit substrate 21 where circuits are disposed can be reduced.

While in FIG. 12 the control signal VR is connected to be input from one buffer circuit 217 to the transistors of four pixels, this is not restrictive. For example, a buffer circuit 217 may be shared by 24 pixels. A buffer circuit 217 may be shared by 48 pixels.

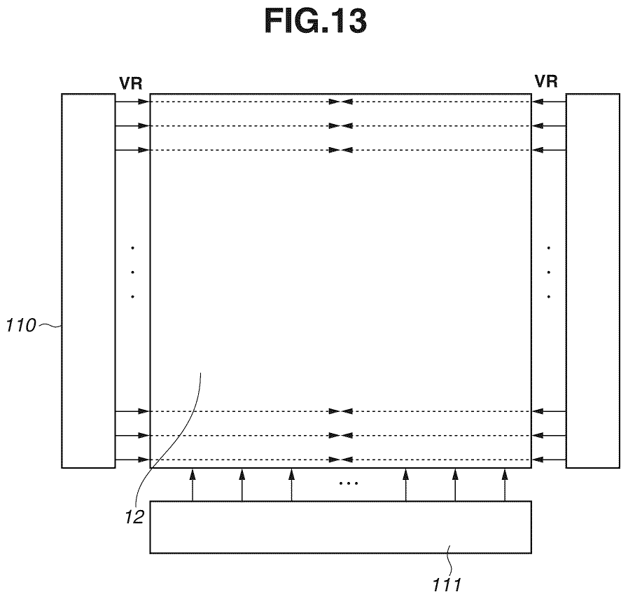

A photoelectric conversion apparatus according to a third exemplary embodiment will be described with reference to FIG. 13. The photoelectric conversion apparatus according to the present exemplary embodiment differs from the second exemplary embodiment in that vertical scanning circuit units 110 are located on both the left and right of the pixel region 12, and control signals VR are input from the left and right of the pixel region 12. Except for this point and the points described below, the third exemplary embodiment is similar to the second exemplary embodiment. Some descriptions may therefore be omitted.

In FIG. 13, the vertical scanning circuit unit 110 (first vertical scanning circuit) located on the right of the pixel region 12 includes a first clock buffer circuit. The control signal VR output from the first clock buffer circuit is connected to be input to a plurality of pixels (first group of APDs) located in the right part among the plurality of pixels disposed on the pixel region 12. The vertical scanning circuit unit 110 (second vertical scanning circuit) located on the left of the pixel region 12 includes a second clock buffer circuit. The control signal VR output from the second clock buffer circuit is connected to be input to a plurality of pixels (second group of APDs) located in the left part among the plurality of pixels disposed on the pixel region 12. The control signal VR to be input to the second group of APDs is supplied via a third wiring layer different from the first wiring layer that inputs the control signal VR to the first group of APDs. Like the first wiring layer, either one or both the thickness and the width of the third wiring layer are greater than those of the second wiring layer.

In the present exemplary embodiment, the number of APDs in the first group and the number of APDs in the second group are the same. However, the numbers of APDs in the first and second groups may be different.

According to the present exemplary embodiment, the distance between the pixels closest to a vertical scanning circuit unit 110 and the pixels farthest from the vertical scanning circuit unit 110 among the pixels connected to the common driving lines 218 can be reduced as compared to the second exemplary embodiment. This can reduce the wiring capacitance of the driving lines 218 for a further reduction in the transmission delay.

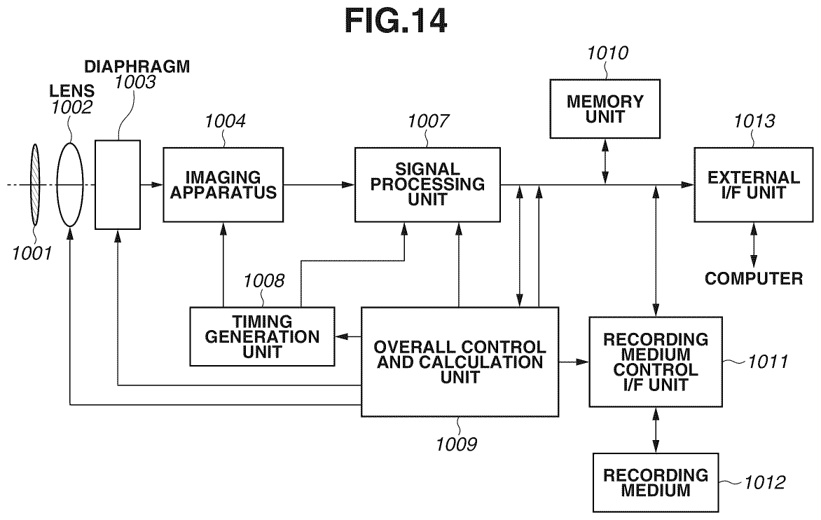

A photoelectric conversion system according to a fourth exemplary embodiment will be described with reference to FIG. 14. FIG. 14 is a block diagram illustrating a schematic configuration of the photoelectric conversion system according to the present exemplary embodiment.

The photoelectric conversion apparatuses described in the foregoing first to third exemplary embodiments can be applied to various photoelectric conversion systems. Examples of the applicable photoelectric conversion systems include a digital still camera, a digital camcorder, a surveillance camera, a copying machine, a facsimile, a mobile phone, an in-car camera, and an observation satellite. A camera module including an optical system, such as a lens, and an imaging device is also included in the photoelectric conversion systems. FIG. 14 illustrates a block diagram of a digital still camera as one of the examples.

The photoelectric conversion system illustrated in FIG. 14 includes an imaging apparatus 1004, a lens 1002 for forming an optical image of an object on the imaging apparatus 1004, a diaphragm 1003 for adjusting the amount of light passing through the lens 1002, and a barrier 1001 for protecting the lens 1002. The lens 1002 and the diaphragm 1003 constitute an optical system for collecting light to the imaging apparatus 1004. The imaging apparatus 1004 is a photoelectric conversion apparatus according to one of the foregoing exemplary embodiments, and converts the optical image formed by the lens 1002 into an electrical signal.

The photoelectric conversion system includes a signal processing unit 1007 that is an image generation unit for generating an image by processing an output signal output from the imaging apparatus 1004. The signal processing unit 1007 performs various types of correction and compression as appropriate, and outputs image data. The signal processing unit 1007 may be formed on a semiconductor substrate where the imaging apparatus 1004 is disposed, or on a separate semiconductor substrate from the imaging apparatus 1004. The imaging apparatus 1004 and the signal processing unit 1007 may be formed on the same semiconductor substrate.

The photoelectric conversion system further includes a memory unit 1010 for temporarily storing the image data, and an external interface (I/F) unit 1013 for communicating with an external computer. The photoelectric conversion system further includes a recording medium 1012, such as a semiconductor memory, for recording and reading captured data, and a recording medium control I/F 1011 for performing recording and reading on the recording medium 1012. The recording medium 1012 may be built in the photoelectric conversion system or detachably attachable to the photoelectric conversion system.

The photoelectric conversion system further includes an overall control and calculation unit 1009 that controls various calculations and the entire digital still camera, and a timing generation unit 1008 that outputs various timing signals to the imaging apparatus 1004 and the signal processing unit 1007. The timing signals may be input from outside, and the photoelectric conversion system can include at least the imaging apparatus 1004 and the signal processing unit 1007 that processes the output signal output from the imaging apparatus 1004.

The imaging apparatus 1004 outputs an imaging signal to the signal processing unit 1007. The signal processing unit 1007 performs predetermined signal processing on the imaging signal output from the imaging apparatus 1004, and outputs image data. The signal processing unit 1007 generates an image using the imaging signal.

According to the present exemplary embodiment, a photoelectric conversion system to which the photoelectric conversion apparatus (imaging apparatus) according to one of the foregoing exemplary embodiments is applied can thus be implemented.

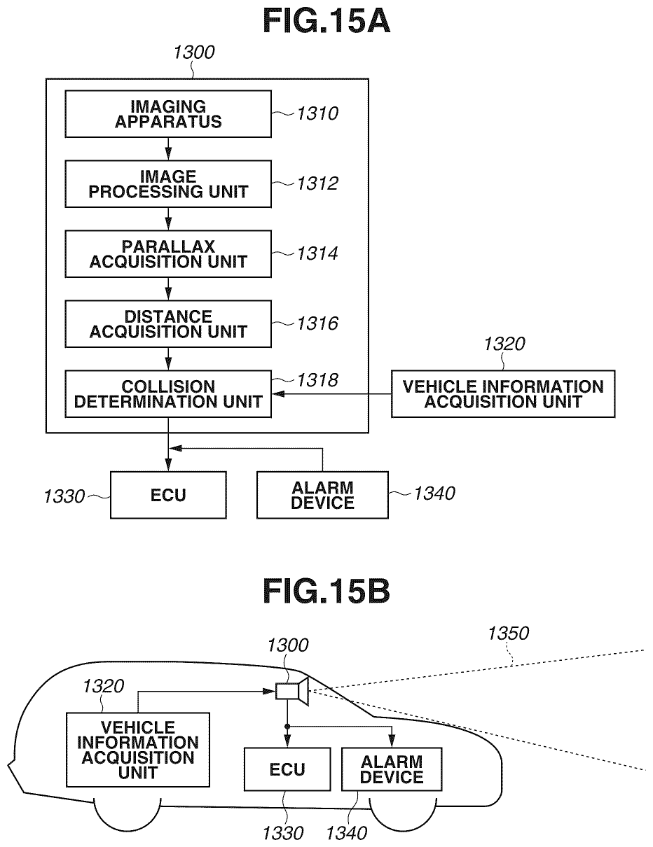

A photoelectric conversion system and a moving body according to a fifth exemplary embodiment will be described with reference to FIGS. 15A and 15B. FIGS. 15A and 15B are diagrams illustrating a configuration of the photoelectric conversion system and the moving body according to the present exemplary embodiment.

FIG. 15A illustrates an example of a photoelectric conversion system related to an in-car camera. A photoelectric conversion system 1300 includes an imaging apparatus 1310. The imaging apparatus 1310 is the photoelectric conversion apparatus (imaging apparatus) according to one of the foregoing exemplary embodiments. The photoelectric conversion system 1300 includes an image processing unit 1312 that performs image processing on a plurality of pieces of image data obtained by the imaging apparatus 1310. The photoelectric conversion system 1300 includes a distance acquisition unit 1316 that calculates a distance to a target object, and a collision determination unit 1318 that determines whether there is a possibility of collision based on the calculated distance. The distance acquisition unit 1316 may acquire distance information about the target object using ToF information, or acquire the distance information using parallax information. In other words, the distance information is information about ToF, parallax, defocusing amount, or the distance to the target object. The collision determination unit 1318 may determine the possibility of collision using any of such pieces of distance information. The distance acquisition unit 1316 (distance information acquisition unit) may be implemented by dedicatedly designed hardware or by a software module. A field-programmable gate array (FPGA) or an application-specific integrated circuit (ASIC) may be used for implementation. A combination of these may be used for implementation.

The photoelectric conversion system 1300 is connected to a vehicle information acquisition unit 1320, and can acquire vehicle information such as vehicle speed, yaw rate, and steering angle. The photoelectric conversion system 1300 is connected to an engine control unit (ECU) 1330, a control device that outputs a control signal for causing a brake force on the vehicle based on the determination result of the collision determination unit 1318. The photoelectric conversion system 1300 is also connected to an alarm device 1340 that issues an alarm to the driver based on the determination result of the collision determination unit 1318. For example, in a case where the determination result of the collision determination unit 1318 indicates a high possibility of collision, the ECU 1330 exercises vehicle control to avoid the collision or reduce damage by applying the brakes, releasing the accelerator, or reducing the engine output. The alarm device 1340 warns the user by sounding an alarm, displaying alarm information on the screen of a car navigation system, or vibrating the seat belt or the steering wheel.

In the present exemplary embodiment, the photoelectric conversion system 1300 captures images of the surroundings of the vehicle, for example, in front or behind. FIG. 15B illustrates the photoelectric conversion system 1300 in the case of capturing images in front of the vehicle (imaging range 1350). The vehicle information acquisition unit 1320 transmits instructions to the photoelectric conversion system 1300 or the imaging apparatus 1310. With such a configuration, the accuracy of distance measurement can be improved.

The foregoing description has dealt with an example of controlling the vehicle to avoid collision with other vehicles. However, the photoelectric conversion system according to the present exemplary embodiment can also be applied to automatic driving control to follow another vehicle or automatic driving control to stay in the lane. Moreover, the photoelectric conversion system is not limited to a vehicle such as an automobile, and can be applied to a moving body (moving apparatus) such as a ship, an aircraft, and an industrial robot, for example. The moving body includes either one or both a driving force generation unit that generates driving force mainly used to move the moving body, and a rotating body mainly used to move the moving body. Examples of the driving force generation unit may include an engine and a motor. Examples of the rotating body may include a tire, a wheel, a ship screw, and an aircraft propeller. The photoelectric conversion system is not limited to a moving body, and can be widely applied to equipment that uses object recognition, such as an intelligent transportation system (ITS).

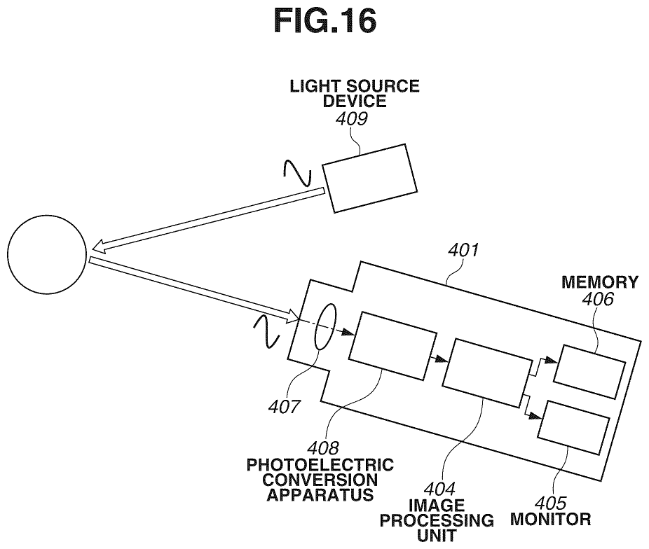

A photoelectric conversion system according to a sixth exemplary embodiment will be described with reference to FIG. 16. FIG. 16 is a block diagram illustrating a configuration example of a distance image sensor that is the photoelectric conversion system according to the present exemplary embodiment.

As illustrated in FIG. 16, a distance image sensor 401 includes an optical system 407, a photoelectric conversion apparatus 408, an image processing circuit 404, a monitor 405, and a memory 406. The distance image sensor 401 can obtain a distance image based on a distance to an object by receiving light (modulated light or pulsed light) that is projected from a light source device 409 toward the object and reflected at the surface of the object.

The optical system 407 includes one or more lenses. The optical system 407 guides the image light (incident light) from the object to the photoelectric conversion apparatus 408 and forms an image on the light receiving surface (sensor unit) of the photoelectric conversion apparatus 408.

The photoelectric conversion apparatus according to one of the foregoing exemplary embodiments is applied as the photoelectric conversion apparatus 408. A distance signal indicating the distance, determined from a light reception signal output from the photoelectric conversion apparatus 408, is supplied to the image processing circuit 404.

The image processing circuit 404 performs image processing for constructing the distance image based on the distance signal supplied from the photoelectric conversion apparatus 408. The distance image (image data) obtained by the image processing is supplied to and displayed on the monitor 405, or supplied to and stored (recorded) in the memory 406.

With the distance image sensor 401 configured thus, the application of the foregoing photoelectric conversion apparatus enables acquisition of a more accurate distance image, for example, because of improved pixel characteristics.

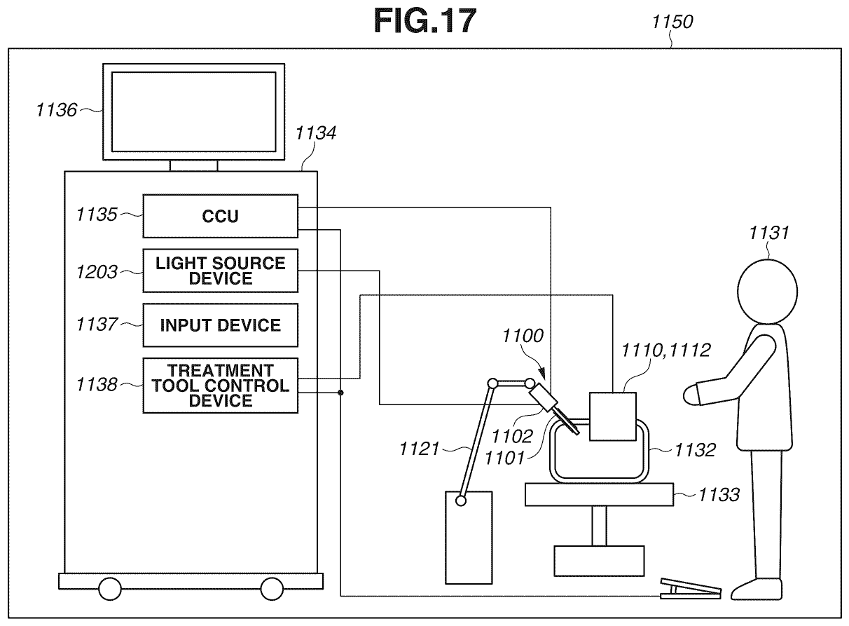

A photoelectric conversion apparatus according to a seventh exemplary embodiment will be described with reference to FIG. 17. FIG. 17 is a diagram illustrating an example of a schematic configuration of an endoscopic surgery system that is the photoelectric conversion system according to the present exemplary embodiment.

FIG. 17 illustrates a state where an operator (doctor) 1131 is performing surgery on a patient 1132 on a patient bed 1133 using an endoscopic surgery system 1150. As illustrated in the diagram, the endoscopic surgery system 1150 includes an endoscope 1100, a surgical tool 1110, and a cart 1134 on which various devices for endoscopic surgery are mounted.

The endoscope 1100 includes a lens barrel 1101, a predetermined length of which from the tip is inserted into a body cavity of the patient 1132, and a camera head 1102 that is connected to the bottom of the lens barrel 1101. In the illustrated example, the endoscope 1100 is configured as a rigid scope with a rigid lens barrel 1101. However, the endoscope 1100 may be configured as a flexible scope with a flexible lens barrel.

The tip of the lens barrel 1101 has an opening with an objective lens fitted thereto. A light source device 1203 is connected to the endoscope 1100. Light generated by the light source device 1203 is guided to the tip of the lens barrel 1101 by a lightguide extended through the lens barrel 1101, and emitted toward an observation target in the body cavity of the patient 1132 through the objective lens. The endoscope 1100 may be a forward-viewing endoscope, an oblique-viewing endoscope, or a side-viewing endoscope.

An optical system and a photoelectric conversion apparatus are disposed inside the camera head 1102. Reflected light (observation light) from the observation target is collected to the photoelectric conversion apparatus through the optical system. The photoelectric conversion apparatus photoelectrically converts the observation light to generate an electrical signal corresponding to the observation light, or equivalently, an image signal corresponding to an observation image. The photoelectric conversion apparatuses (imaging apparatuses) described in the foregoing exemplary embodiments can be used as the photoelectric conversion apparatus. The image signal is transmitted to a camera control unit (CCU) 1135 as raw data.

The CCU 1135 includes a central processing unit (CPU) and a graphics processing unit (GPU), and controls the operation of the endoscope 1100 and a display device 1136 in a centralized manner. The CCU 1135 receives the image signal from the camera head 1102, and applies various types of image processing for displaying an image based on the image signal, such as development processing (demosaicing processing), to the image signal.

The display device 1136 displays an image based on the image signal to which the image processing is applied by the CCU 1135, under control of the CCU 1135.

The light source device 1203 includes a light source such as a light-emitting diode (LED), for example, and supplies illumination light to the endoscope 1100 in capturing an image of a surgical site.

An input device 1137 is an input I/F for the endoscopic surgery system 1150. The user can input various types of information and instructions to the endoscopic surgery system 1150 via the input device 1137.

A treatment tool control device 1138 controls driving of an energy treatment tool 1112 for tissue cauterization, cutting, or sealing of blood vessels.

The light source device 1203 that supplies the endoscope 1100 with the illumination light in capturing an image of the surgical site can include an LED, a laser light source, a group of color LEDs, or a white light source constituted by a group of color LEDs, for example. In a case where the white light source is constituted by combining red, blue, and green (RGB) laser light sources, the white balance of the captured image can be adjusted by the light source device 1203 since the output intensity and output timing of each color (wavelength) can be controlled with high precision. In such a case, images corresponding to the respective colors R, G, and B can be captured in a time-division manner by irradiating the observation target with the respective laser beams from the RGB laser light sources in a time-division manner and controlling the driving of the image sensor of the camera head 1102 in synchronization with the irradiation timing. According to such a method, a color image can be obtained without providing color filters on the image sensor.

The driving of the light source device 1203 can be controlled so that the intensity of the output light changes at predetermined time intervals. A high dynamic range image with no underexposure or overexposure can be generated by controlling the driving of the image sensor of the camera head 1102 in synchronization with the changing timing of the light intensity to obtain images in a time-division manner and combining the images.

The light source device 1203 may be configured so that light in a predetermined wavelength band for special light observation can be supplied. Special light observation uses the wavelength dependence of light absorption by body tissues, for example. Specifically, a high-contrast image of predetermined tissues such as blood vessels in the mucosal surface layer is captured by irradiating the mucosal surface layer with narrow-band light compared to the illumination light used in normal observation (i.e., white light).

As another example of special light observation, fluorescence observation may be performed to obtain images based on fluorescence caused by excitation light irradiation. In fluorescence observation, fluorescent images can be obtained by irradiating body tissues with excitation light and observing fluorescence from the body tissues, or by locally injecting a reagent, such as indocyanine green (ICG), into body tissues and irradiating the body tissues with excitation light corresponding to the fluorescence wavelength of the reagent. The light source device 1203 can be configured to be capable of supplying narrow-band light and/or excitation light for such special light observation.

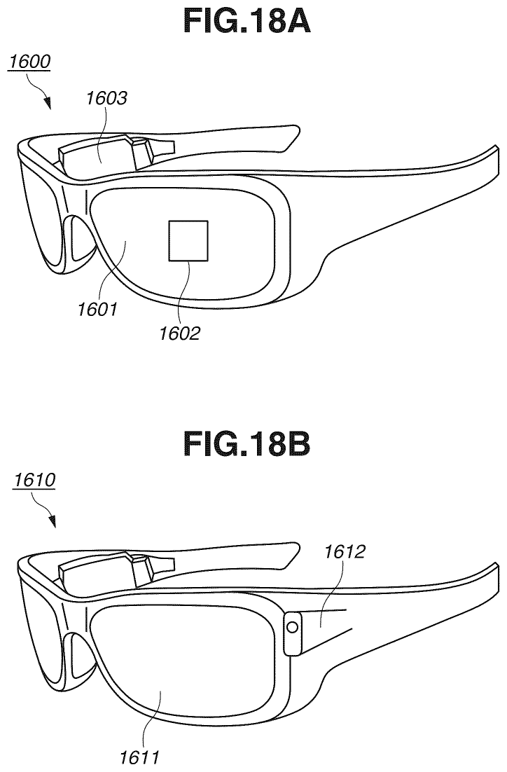

A photoelectric conversion system according to an eighth exemplary embodiment will be described with reference to FIGS. 18A and 18B. FIG. 18A illustrates glasses 1600 (smart glasses) that are the photoelectric conversion system according to the present exemplary embodiment. The glasses 1600 include a photoelectric conversion apparatus 1602. The photoelectric conversion apparatus 1602 is the photoelectric conversion apparatus (imaging apparatus) according to one of the foregoing exemplary embodiments. A display device including a light emitting device such as an organic light-emitting diode (OLED) and an LED may be disposed on the backside of a lens 1601. The number of photoelectric conversion apparatuses 1602 may be one or more. A plurality of types of photoelectric conversion apparatuses may be used in combination. The layout position of the photoelectric conversion apparatus 1602 is not limited to that in FIG. 18A.

The glasses 1600 further include a control apparatus 1603. The control apparatus 1603 functions as a power supply for supplying power to the photoelectric conversion apparatus 1602 and the display device. The control apparatus 1603 controls operation of the photoelectric conversion apparatus 1602 and the display device. The lens 1601 includes an optical system for collecting light to the photoelectric conversion apparatus 1602.

FIG. 18B illustrates glasses 1610 (smart glasses) according to an application example. The glasses 1610 include a control apparatus 1612. The control apparatus 1612 includes a photoelectric conversion apparatus corresponding to the photoelectric conversion apparatus 1602, and a display device. The photoelectric conversion apparatus in the control apparatus 1612 and an optical system for projecting light emitted from the display device are formed on a lens 1611, and an image is projected on the lens 1611. The control apparatus 1612 functions as a power supply for supplying power to the photoelectric conversion apparatus and the display device, and controls operation of the photoelectric conversion apparatus and the display device. The control apparatus 1612 may include a line of sight detection unit that detects the wearer's line of sight. The line of sight may be detected using infrared rays (infrared light). An infrared light emission unit emits infrared rays to an eyeball of the user gazing at a displayed image. An imaging unit including a light receiving element detects reflection of the emitted infrared rays from the eyeball, whereby a captured image of the eyeball can be obtained. The glasses 1610 include a reduction unit configured to reduce light from the infrared light emission unit to the display unit in a plan view, whereby a drop in image quality is reduced.

The user's line of sight to the displayed image can be detected from the captured image of the eyeball obtained by the infrared imaging. Any conventional technique can be applied to the line of sight detection using the captured image of the eyeball. For example, a line of sight detection method based on a Purkinje image formed by the reflection of the illumination light on the cornea can be used.

More specifically, line of sight detection processing based on the pupil-cornea reflection method is performed. The user's line of sight is detected by calculating a line of sight vector indicating the direction (rotation angle) of the eyeball based on the pupil image and the Purkinje image included in the captured image of the eyeball, using the pupil-cornea reflection method.

The display device according to the present exemplary embodiment may include a photoelectric conversion apparatus including a light receiving element and control the displayed image on the display device based on the user's line of sight information from the photoelectric conversion apparatus.

Specifically, the display device determines a first field of view region that the user is gazing at and a second field of view region other than the first field of view region, based on the line of sight information. The first field of view region and the second field of view region may be determined by a control apparatus of the display device. First and second field of view regions determined by an external control apparatus may be received. The display resolution of the first field of view region on the display region of the display device may be controlled to be higher than that of the second field of view region. In other words, the second field of view region may have a reduced resolution compared to the first field of view region.

The display region may include a first display region and a second display region different from the first display region, and a region of higher priority may be determined between the first and second display regions based on the line of sight information. The first and second display regions may be determined by the control apparatus of the display device. First and second display regions determined by an external control apparatus may be received. The resolution of the region of higher priority may be controlled to be higher than that of the region other than the region of higher priority. In other words, the region of relatively low priority may have a reduced resolution.

The first field of view region or the region of higher priority may be determined using artificial intelligence (AI). The AI may be a model that is configured to estimate the angle of the line of sight and the distance to an object in front of the line of sight from the eyeball image, with eyeball images and the actual viewing directions of the eyeballs in the images as training data. Such an AI program may be included in the display device, the photoelectric conversion apparatus, or an external apparatus. In a case where the external apparatus includes the AI program, the estimation results are transmitted to the display device through communication.

In a case where display control is performed based on visual detection, smart glasses further including a photoelectric conversion apparatus for capturing the outside can be suitably applied. The smart glasses can display the captured external information in real time.

A ninth exemplary embodiment will be described. The foregoing photoelectric conversion apparatuses and photoelectric conversion systems may be applied to an electronic device such as a smartphone and a tablet.

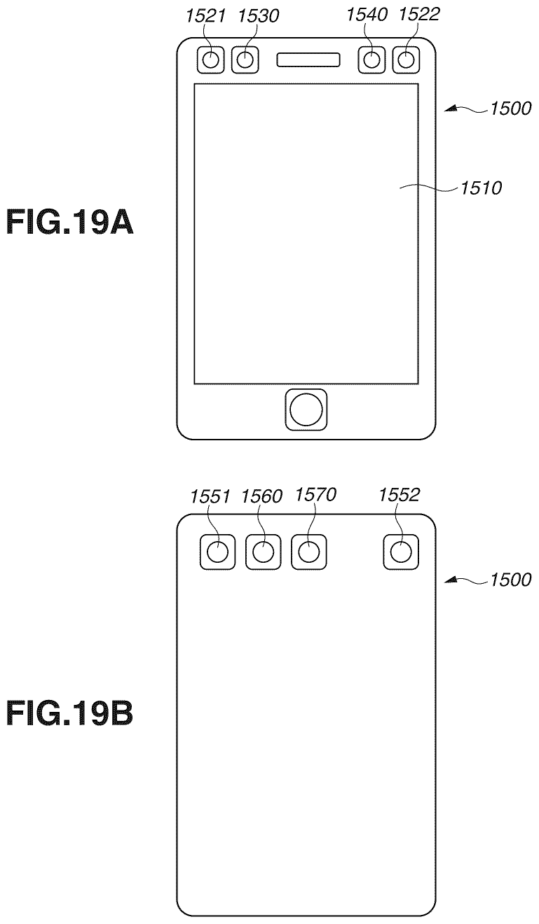

FIGS. 19A and 19B are diagrams illustrating an example of an electronic device 1500 on which photoelectric conversion apparatuses are mounted. FIG. 19A illustrates the front side of the electronic device 1500. FIG. 19B illustrates the rear side of the electronic device 1500.

As illustrated in FIG. 19A, a display 1510 for displaying images is located in the center of the front of the electronic device 1500. Front cameras 1521 and 1522 using photoelectric conversion apparatuses, an infrared (IR) light source 1530 for emitting IR rays, and a visible light source 1540 for emitting visible light are arranged along the top edge of the front of the electronic device 1500.

As illustrated in FIG. 19B, rear cameras 1551 and 1552 using photoelectric conversion apparatuses, an IR light source 1560 for emitting IR rays, and a visible light source 1570 for emitting visible light are arranged along the top edge of the back of the electronic device 1500.

With the electronic device 1500 configured thus, the application of the foregoing photoelectric conversion apparatuses enables capturing images of higher quality, for example. The photoelectric conversion apparatuses can also be applied to other electronic devices such as an IR sensor, a distance measurement sensor using an IR light source, a security camera, and a personal or biometric authentication camera. The accuracy and performance of such electronic devices can thereby be improved.

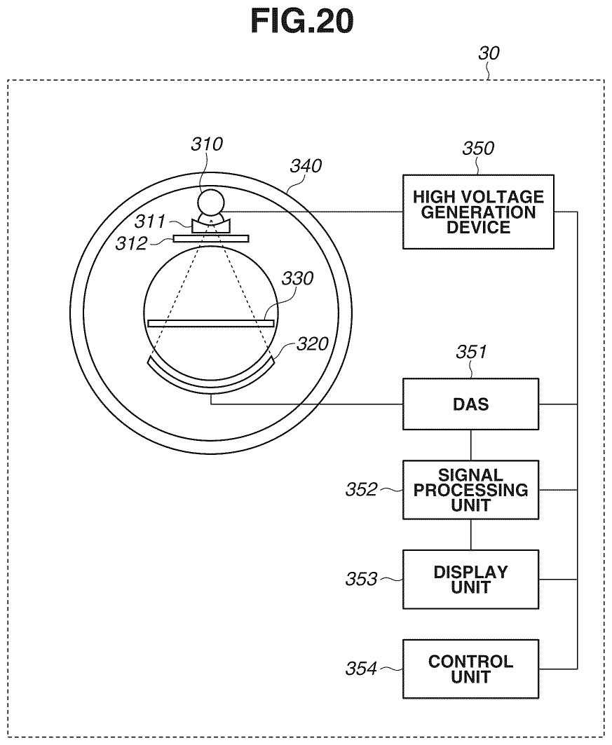

FIG. 20 is a block diagram of an X-ray computed tomography (CT) device according to a tenth exemplary embodiment. The photoelectric conversion apparatuses according to the first to third exemplary embodiments can be applied to the detector of the X-ray CT device. An X-ray CT device 30 according to the present exemplary embodiment includes an X-ray generation unit 310, a wedge 311, a collimator 312, and an X-ray detection unit 320. The X-ray CT device 30 further includes a top plate 330, a rotating frame 340, a high voltage generation device 350, a data acquisition system (DAS) 351, a signal processing unit 352, a display unit 353, and a control unit 354.

The X-ray generation unit 310 includes a vacuum tube that generates X-rays, for example. A high voltage and a filament current from the high voltage generation device 350 are supplied to the vacuum tube of the X-ray generation unit 310. X-rays are generated by irradiating the anode (target) with thermionic electrons from the cathode (filament).

The wedge 311 is a filter for adjusting the amount of X-rays emitted from the X-ray generation unit 310. The wedge 311 attenuates the amount of X-rays so that the X-rays emitted from the X-ray generation unit 310 to a subject have a predetermined distribution. The collimator 312 includes lead plates for narrowing the irradiation range of the X-rays transmitted through the wedge 311. The X-rays generated by the X-ray generation unit 310 are shaped into a cone beam through the collimator 312, and the subject on the top plate 330 is irradiated with the cone beam.

The X-ray detection unit 320 includes the photoelectric conversion apparatus according to the foregoing second or third exemplary embodiment. The X-ray detection unit 320 detects the X-rays transmitted through the object from the X-ray generation unit 310, and outputs a signal corresponding to the amount of X-rays to the DAS 351.

The rotating frame 340 has an annular shape and is configured to be rotatable. The X-ray generation unit 310 (wedge 311 and collimator 312) and the X-ray detection unit 320 are opposed to each other inside the rotating frame 340. The X-ray generation unit 310 and the X-ray detection unit 320 can rotate with the rotating frame 340.

The high voltage generation device 350 includes a boosting circuit, and outputs a high voltage to the X-ray generation unit 310. The DAS 351 includes an amplification circuit and an analog-to-digital (A/D) conversion circuit, and outputs the signal from the X-ray detection unit 320 to the signal processing unit 352 as digital data.

The signal processing unit 352 includes a CPU, a read-only memory (ROM), and a random access memory (RAM), and can perform image processing on the digital data. The display unit 353 includes a flat display device, and can display X-ray images. The control unit 354 includes a CPU, a ROM, and a RAM, and controls operation of the entire X-ray CT device 30.

While the foregoing exemplary embodiments have been described based on the configuration of a stacked sensor where the first substrate and the second substrate are stacked, the exemplary embodiments are not limited to such an example. In other words, all the members illustrated in FIGS. 2 and 3 may be disposed on a single substrate. Even in such a case, the effect of the exemplary embodiments that the transmission delay of the control signal VR can be reduced can be obtained.

In this specification, expressions such as “A or B”, “at least one of A and B”, “at least one of A and/or B”, and “one or more of A and/or B” may be used. Such expressions can include all possible combinations of the cited items unless otherwise explicitly defined. In other words, the foregoing expressions are understood to disclose all cases where at least A is included, where at least B is included, and where at least A and at least B are both included. The same applies to combinations of three or more elements.

The exemplary embodiments described above can be modified as appropriate without departing from the technical concept. The disclosure of this specification includes not only what is described in this specification but all matters comprehensible from this specification and the drawings attached to this specification. The disclosure of this specification includes the complementary of the set of concepts described in this specification as well. In other words, if, for example, this specification states, “A is greater than B”, it can be said that this specification discloses “A is not greater than B” even in a case where the statement “A is not greater than B” is omitted. The reason is that when stating “A is greater than B”, it is presumed that the possibility of “A is not greater than B” has been considered.

According to an exemplary embodiment of the disclosure, a technique advantageous in reducing the transmission delay of a control signal to be input to transistors that control the occurrence of avalanche multiplication is provided.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-166369, filed Sep. 27, 2023, which is hereby incorporated by reference herein in its entirety.

What is claimed is:

1. An apparatus comprising:
a plurality of avalanche photodiodes;
a plurality of transistors connected to the plurality of avalanche photodiodes and configured to control occurrence of avalanche multiplication;
a first wiring layer configured to transmit a control signal to be input to gates of the plurality of transistors; and
a second wiring layer configured to read signals from the avalanche photodiodes,
wherein the plurality of avalanche photodiodes includes a first group of avalanche photodiodes arranged in a first direction,
wherein the plurality of transistors includes a first group of transistors connected to the first group of avalanche photodiodes,
wherein the first wiring layer is connected in common to the first group of transistors, and
wherein the first wiring layer has a thickness greater than a thickness of the second wiring layer.

2. The apparatus according to claim 1, further comprising a first clock buffer circuit,
wherein the first clock buffer circuit is configured to supply the control signal to the first wiring layer.

3. The apparatus according to claim 2, further comprising a plurality of buffer circuits connected to the first wiring layer,
wherein one of the buffer circuits is shared by some transistors in the first group of transistors.

4. The apparatus according to claim 2, further comprising a first vertical scanning circuit, a second vertical scanning circuit, and a second clock buffer circuit,
wherein the plurality of avalanche photodiodes includes a second group of avalanche photodiodes arranged in a same direction as the first group of avalanche photodiodes,
wherein the plurality of transistors includes a second group of transistors connected to the second group of avalanche photodiodes,
wherein the control signal is transmitted to the second group of transistors via a third wiring layer,
wherein the first clock buffer circuit is disposed in the first vertical scanning circuit,
wherein the second clock buffer circuit is disposed in the second vertical scanning circuit, and
wherein the second clock buffer circuit is configured to supply the control signal to the third wiring layer.

5. The apparatus according to claim 4, wherein the number of transistors in the first group and the number of transistors in the second group are same.

6. The apparatus according to claim 5, further comprising a plurality of buffer circuits connected to the first wiring layer,
wherein one of the buffer circuits is shared by some transistors in the first group of transistors.

7. The apparatus according to claim 1, wherein the first wiring layer has a width greater than a width of the second wiring layer.

8. The apparatus according to claim 4, wherein the third wiring layer has a thickness greater than the thickness of the second wiring layer.

9. The apparatus according to claim 1, wherein the first wiring layer has a thickness 1.2 times or more of the thickness of the second wiring layer.

10. The apparatus according to claim 9, wherein the thickness of the first wiring layer is in a range of 12 nm to 2000 nm, and the thickness of the second wiring layer is in a range of 10 nm to 1000 nm.

11. An apparatus comprising:
a plurality of avalanche photodiodes;
a plurality of transistors connected to the plurality of avalanche photodiodes and configured to control occurrence of avalanche multiplication;
a first wiring layer configured to transmit a control signal to be input to gates of the plurality of transistors; and
a second wiring layer configured to read signals from the avalanche photodiodes,
wherein the plurality of avalanche photodiodes includes a first group of avalanche photodiodes arranged in a first direction,
wherein the plurality of transistors includes a first group of transistors connected to the first group of avalanche photodiodes,
wherein the first wiring layer is connected in common to the first group of transistors, and
wherein the first wiring layer has a width greater than a width of the second wiring layer.

12. The apparatus according to claim 11, further comprising a first clock buffer circuit,
wherein the first clock buffer circuit is configured to supply the control signal to the first wiring layer.

13. The apparatus according to claim 12, further comprising a plurality of buffer circuits connected to the first wiring layer,
wherein one of the buffer circuits is shared by some transistors in the first group of transistors.

14. The apparatus according to claim 13, further comprising a first vertical scanning circuit, a second vertical scanning circuit, and a second clock buffer circuit,
wherein the plurality of avalanche photodiodes includes a second group of avalanche photodiodes arranged in a same direction as the first group of avalanche photodiodes,
wherein the plurality of transistors includes a second group of transistors connected to the second group of avalanche photodiodes,
wherein the control signal is transmitted to the second group of transistors via a third wiring layer,
wherein the first clock buffer circuit is disposed in the first vertical scanning circuit,
wherein the second clock buffer circuit is disposed in the second vertical scanning circuit, and
wherein the second clock buffer circuit is configured to supply the control signal to the third wiring layer.

15. An apparatus comprising:
a plurality of avalanche photodiodes;
a plurality of transistors connected to the plurality of avalanche photodiodes and configured to control occurrence of avalanche multiplication;
a first wiring layer configured to transmit a control signal to be input to gates of the plurality of transistors; and
a second wiring layer configured to read signals from the avalanche photodiodes,
wherein the plurality of avalanche photodiodes includes a first group of avalanche photodiodes arranged in a first direction,
wherein the plurality of transistors includes a first group of transistors connected to the first group of avalanche photodiodes,
wherein the first wiring layer is connected in common to the first group of transistors, and
wherein the first wiring layer has a wiring resistance lower than a wiring resistance of the second wiring layer.

16. A system comprising:
the apparatus according to claim 1; and
a signal processing unit configured to generate an image using a signal output from the apparatus.

17. A moving body comprising:
the apparatus according to claim 1; and
a control unit configured to control movement of the moving body using a signal output from the apparatus.

18. A system comprising:
the apparatus according to claim 11; and
a signal processing unit configured to generate an image using a signal output from the apparatus.

19. A moving body comprising:
the apparatus according to claim 11; and
a control unit configured to control movement of the moving body using a signal output from the apparatus.

20. A system comprising:
the apparatus according to claim 15; and
a signal processing unit configured to generate an image using a signal output from the apparatus.

21. A moving body comprising:
the apparatus according to claim 15; and
a control unit configured to control movement of the moving body using a signal output from the apparatus.
